(19) United States
(12) Patent Application Publication
(10) Pub. No.: US 2003/0116346 A1
(43) Pub. Date: Jun. 26, 2003

(54) Low cost area array probe for circuits having solder-ball contacts are manufactured using a wire bonding machine

(76) Inventors: James Allam Forster, Barrington, RI (US); Reynaldo M. Rincon, Richardson, TX (US); Richard Amold, McKinney, TX (US); Lester Wilson, Sherman, TX (US)

Correspondence Address: TEXAS INSTRUMENTS INCORPORATED, P O BOX 655474, M/S 3999, DALLAS, TX, 75265

(21) Appl. No.: 10/026,052

(22) Filed: Dec. 21, 2001

(51) Int. Cl. H05K 1/11; H05K 7/06

(52) U.S. Cl. 174/257; 174/260; 174/250; 29/843; 29/842

(57) ABSTRACT

An inexpensive and accurate probe card for testing integrated circuits such as DSPs and the like which have solder ball contact points as manufactured by using a commercially available wire bonding machine. Conductive members or stud bumps are deposited or bonded to conductive pads formed on an insulating substrate. According to one embodiment, three stud bumps are formed on each pad to create an interconnecting nest to receive these solder ball contacts.

### FIELD OF THE INVENTION

This invention relates to probe cards used for testing circuits having solder-ball connections and/or contact points. More specifically the invention relates to inexpensive and accurate probe cards for testing, and the manufacturing of such cards inexpensively, rapidly and accurately by the use of a wire bonding machine.

### BACKGROUND OF THE INVENTION

The manufacture of probe cards that provide temporary interconnections for testing present day IC's (Integrated Circuits) is becoming more difficult and expensive as the pitch of the circuit die narrows or becomes smaller. The conventional technologies now used for interconnecting area array solder bumps are simply too difficult to build and adapt to modern probe technology needs. Probe cards are needed that can be assembled with low cycle time and that allow the locations of the temporary contact points that connect with the solder balls of the area array die to be readily changed. As the present day complex circuits include smaller and more numerous solder balls the damage to the solder balls during the probing or testing process creates problems with the assembly process used for attaching the circuit to the package, substrate or lead frame. Area array probe cards manufactured according to the prior art often cost more than $100K. The high density and pin-count on the cards make them very difficult to build and often require up to a six-month lead time to accommodate the design and manufacture of the card. Further, once the cards are built they are difficult to maintain and if repair is required they may require return to the factory. The long cycle time for designing and building does not meet the needs of the production cycles that that present day chip manufactures need to deliver products in the competitive and fast paced environment that exists.

Various present area array probe interconnection technologies are shown and discussed with respect to FIGS. 1 through 6. Each of these technologies, although proven successful, do have significant technical drawbacks that limit the capability to rapidly manufacture and maintain low cost probe cards.

The Metal Pinch Contact illustrated in FIG. 1 has elongated arms 20 that are attached to the interconnection contact points (not shown). The contacts for the “Metal Pinch” approach are very difficult to build and place into a socket that will keep the contact probe oriented toward the backside of the solder ball.

The Metal Y Contact shown in FIG. 2 often damages the solder ball in the critical contact area used for attaching the die to the package. This approach also has elongated arms 20 and consequentially may experience some of the manufacturing difficulties as the “Metal Pinch Contact” approach.

The Rough Bump illustrated in FIG. 3 is difficult to assemble and constantly requires cleaning up the solder material that is left on the jagged edges of the rough bump. FIG. 3a shows the flattened and rough surface 22 of the solder ball 24 after contact with the rough Bump on a probe or flex card. A solder ball that has suffered this damage will be difficult to attach to the package.

The Conductive Polymer Bump upon Ceramic illustrated in FIG. 4 is expensive to build and requires a change in the photo-mask, since the polymer material 26 is screened onto the ceramic surface of a photo mask used to manufacture the card. The conductive polymer is often unable to withstand the high temperature required in IC testing and will break down.

The Etched Pocket in Silicon shown in FIG. 5 is expensive to build because of the necessity of a photo-mask and expensive processing to build up the pockets or nests that receive the solder bumps. This style of contact is also difficult to keep clean, as the solder material from the solder balls tend to clump in the corners of the pocket with repeated contacts. FIG. 5a shows a top view of the damage to the solder bump created by the use of the Etched Pocket technology. Note that the solder ball assumes the shape 28 of the pocket and is significantly deformed.

The Metal Probe shown in FIG. 6 is difficult to keep aligned to the solder bumps, and often causes damage to the solder bumps similar to the damage caused by the “Etched Pocket of FIG. 5. This damage can cause severe yield loss because of failure to attach the die to the package or substrate.

Thus it is seen that except for the Metal Pinch Contact approach, unacceptable damage can occur to the solder ball contact during the probing process.

### SUMMARY OF THE INVENTION

Objects and advantages of the invention will in part be obvious, and will in part be accomplished by the present invention which provides apparatus and methods for testing circuitry having an array of solder-ball contacts of a selected size and having a contact area and a periphery area. The invention comprises a support substrate having a working surface and a multiplicity of conductive pads formed or mounted on the working surface. A multiplicity of conductive pathways such as wires or conductive traces deposited or formed on the substrate extend from the multiplicity of conductive pads to test circuitry. At least one conductive member is formed on each of the multiplicity of conductive pads and extends away from the working surface. The conductive members formed on the conductive pads are positioned on the support substrate so as to make an electrical connection with the peripheral area of the solder-ball contact points on a circuit which is placed against the apparatus. The array of contact points or solder-ball connections are typically of a uniform size and include a contact area and a periphery area.

According to one embodiment, the conductive members are short lengths of wire or stud bumps deposited on the conductive pads by a wire bonding machine and are typically formed from gold wire or aluminum wire. Alternately, the length of wire deposited by the wire bonding machine may comprise a formed length of wire having each end bonded or mounted to a conductive pad, and a raised area or peak in the middle of the length of wire. The length of wire with the raised area may be dipped or covered with a mold compound to provide rigidity. The support substrate comprises a planar non-conducting or insulating material and the conductive pathways are typically conductive traces formed or deposited on the planar material. The conductive pathways may be formed on the working surface, or alternately the conductive pathways may be formed on the surface opposite the working surface and include a conductive via extending from the opposite surface through the non-conductive material to one of the conductive pads on the working surface. The conductive members may alternately comprise two or more stud bumps bonded on top of each other.

According to another embodiment, each pad includes at least three conductive lengths of wire or stud bumps attached at one end only and extending away from the working surface. These lengths of wire or stud bumps are also deposited on the conductive pads by a wire bonding machine so as to form an interconnecting nest. The interconnecting nest is positioned on the support substrate so as to receive a solder-ball contact point and to make an electrical connection with the peripheral area of the received solder-ball, while avoiding the permanent connection area.

### BRIEF DESCRIPTION OF THE DRAWINGS

FIG. 1 shows a prior art “Metal Pinch Contact” testing or temporary interconnect contact point for use on a probe card.

FIG. 2 is a prior art “Metal Y” temporary interconnect contact available for use on the probe card.

FIG. 3 is a prior art “Rough Bump” temporary interconnect contact available for use on a probe card.

FIG. 3a illustrates the damage caused by the “Rough Bump” contact technology described with respect to FIG. 3.

FIG. 4 is a prior art illustration of a conductive “Polymer” temporary interconnect available for use on a probe card.

FIG. 5 is a prior art illustrates of an “Etched Pocket” temporary interconnect available for use on a probe card.

FIG. 5a illustrates the damage by the “Etched Pocket” temporary interconnect discussed with respect to FIG. 5.

FIG. 6 is a prior art illustration of “Metal Probe” temporary interconnect available for use on a probe card.

FIG. 7 shows typical solder ball contact or connection point and illustrates the areas of the contact used to make a permanent connection during assembly and/or packaging of the circuit, and the peripheral area suitable for temporary contacts during testing.

FIGS. 8-11 illustrate conductive members or stud bump contacts as deposited by a wire bonding machine to manufacture a card probe having one stud bump, two stud bumps, three stud bumps and four stud bumps, respectively, for contacting the solder ball connections.

FIGS. 12-17 illustrate various types of conductive member or stud bumps which may be deposited by a wire bonding machine for use as the conductive members for contacting the solder ball connections.

FIG. 18 shows a view of a probe card illustrating conductive pads with an interconnect nest formed by three stud bumps.

FIG. 19 illustrates an alternate embodiment for providing pathways from the conductive pads with the stud bumps to testing circuitry.

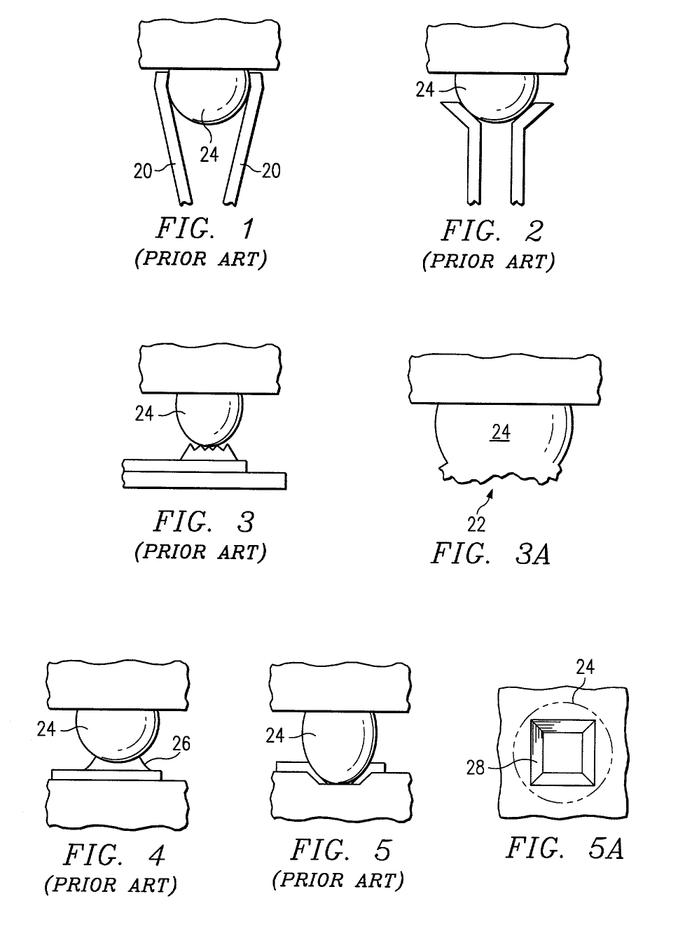

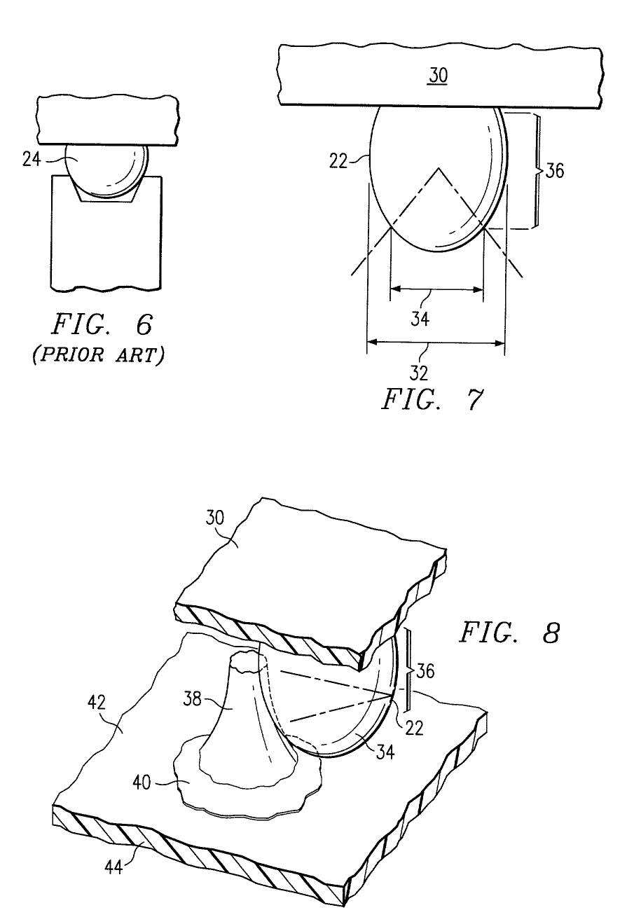

### DESCRIPTION OF EMBODIMENTS

An optimal testing probe card will keep the probe tips from contacting a “Keep out Zone” which is the permanent connection area of the solder-ball contact. To accomplish this, the probe tips or conductive members are designed so that their placement avoids the Keep out Zone. Consequently, the yield loss that occurs due to the deformation of the solder-ball or bump is minimized.

Referring now to FIG. 7, there is illustrated a solder ball contact or connection point which shows the area used to make a permanent connection during assembly and/or packaging of a circuitry, and the peripheral area suitable for use during testing of the circuitry. As shown, the solder ball or connecting point 22 is bonded to the substrate or chip 30. Further, assuming a solder ball contact with a typical diameter (see reference number 24) between about 0.007 and 0.008 inches, the permanent contact area 34 has a diameter of about 0.005 inches. To avoid damage to the solder ball area used for permanent connections, the contact area 34 is not used during testing. The peripheral area 36, however, is available for use. The present invention provides a probe that uses the peripheral area 36 and avoids the contact area 34 during the testing process and also discloses a process for manufacturing this type of probe cards.

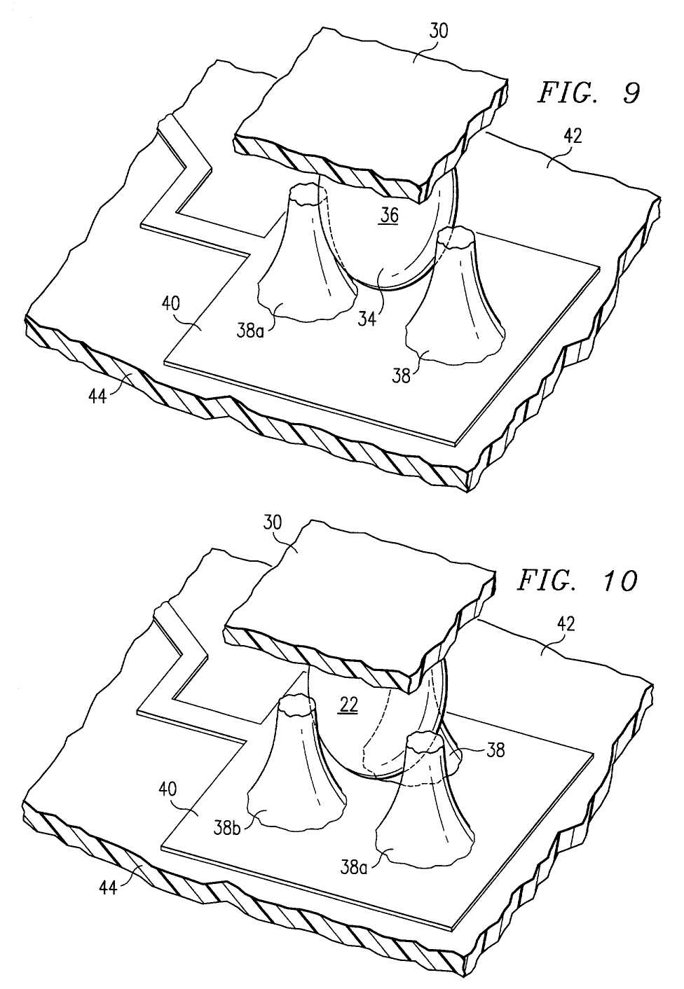

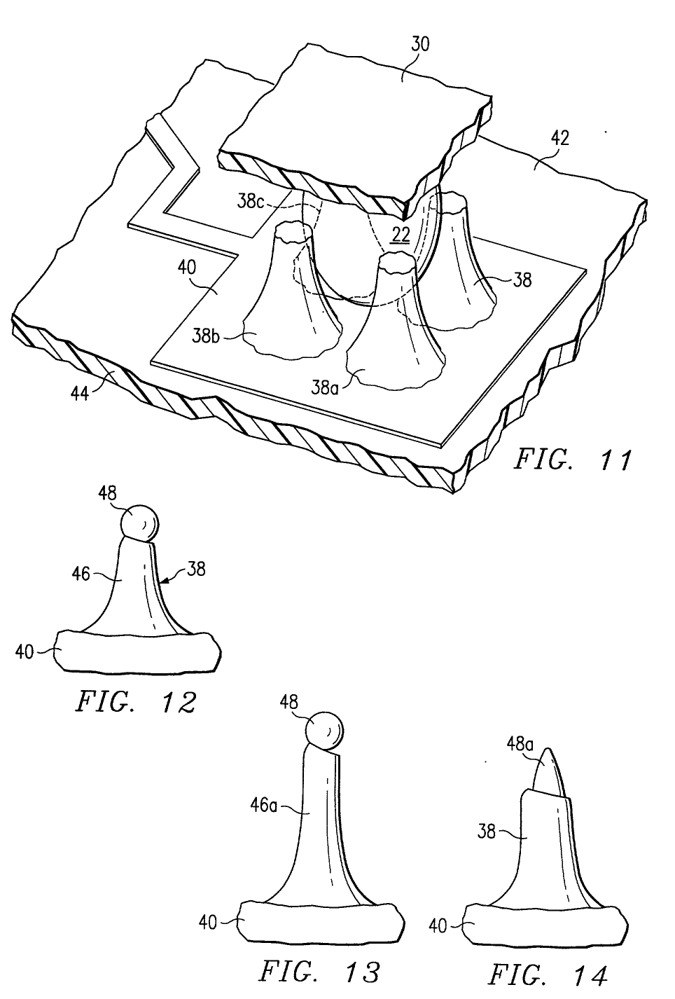

FIGS. 8-11 show elevation views of various conductive members or stud bumps formed or deposited on probe cards according to the teachings of the invention. These conductive members make side contact with the peripheral area 36 of solder ball contacts or connection points on an IC. As shown in each of the FIGS. 8-11, a peripheral area 36 of the solder ball 22 located on a chip 30 makes contact with the conductive member such as a stud bump 38 deposited by a wire bonding machine on a conductive pad 40, which in turn is formed on the working surface 42 of a substrate or support substrate 44. In FIG. 8, conductive pad 40 is shown as a round pad, but as will be appreciated could be any chosen shape, and may preferably be rectangular as shown in the embodiments of FIGS. 9-11. FIGS. 8 and 9 illustrate a single conductive member 38 and two conductive members 38a and 38b respectively deposited on a conductive pad 40 which will contact the peripheral areas 36 on solder ball contact 22. FIGS. 10 and 11 illustrate how using three or more conductive members or stud bumps 38, 38a, 38b. 38c and 38d, creates a nest area that receives the solder ball contact 22 and substantially assures an electrical connection.

As mentioned above, it has been found that commercially available wire bonding machines are particularly useful in manufacturing probe cards having conductive contact members of the type illustrated in FIGS. 8-11. As mentioned, various commercially available wire bonding machines are suitable for use with this invention so long as they have the accuracy to place the stud bumps precisely on the conductive pads. For example, one suitable wire bonding machine is Model No. K&S 8028 machine available from Kulicke & Soffa company at 143 Witmer Rd., Willow Grove, Pa. 19090.

The use of an IC Wire Bonding Machine to place, form and shape the area array conductive members or stud bumps provides a low cost and flexible means to build the area array probe head for wafer and die interconnection. The wire bonding machine has been shown to deposit or form the conductive members or “Stud Bumps” with gold or aluminum wire that can be used to manufacture an effective and inexpensive interconnection area array probe card. The stud bumps can be placed with great precision in the exact location as directed by the software controlling the wire bonding machine to form the contacts for a temporary interconnection between the solder ball on the IC and the electrical probe needed for IC testing and burn-in. The wire bonding machine operates in the normal manner used to permanently connect Gold or Aluminum wire between the IC and the package or lead frame. The wire bonding machine can also shape the wire in different shapes that are useful in building a probe tip that can avoid the permanent contact area 34 of the solder ball on the die while contacting the peripheral area 36. Commercial wire bonding machines are so precise that they can be used to place stud bumps on top of already bonded stud bumps. Thus, the wire bonding machine provides a method to manufacture area array probe cards at a very low price. Automated wire bonding machines are readily available and at a low enough cost that a manufacturer of probe cards may chose to adapt the use of stud bumps placed or formed by the machines to replace their regular process of manufacturing probe cards. Presently the manufacture of area array cards is a very tedious design and manufacturing process that often relies upon hand assembly of the probe cards. In addition, the use of an automated process for accurately placing the stud bumps enables the probe card to be modified whenever the designer needs change the configuration of the stud bump array. Further, automation of the probe card manufacturing process cuts the cycle time down to days instead of months in the designing and building of probe cards

The wire bonding machine can build or deposit stud bumps in different shapes that can be advantageously selected to form a temporary probe or conductive member to contact the solder ball. In addition, different wire sizes can be used to optimize the interconnection surface or shape and the stiffness of the contact. FIG. 8 shows one of the possible shapes of the conductive member or stud bumps to achieve an excellent electrical connection with the solder ball contacts. As was discussed in more detail heretofore, these stud bumps can be placed in a triangular, square or other shape so that the solder bump is received in the center of the “nest” formed by the stud bump connectors. The stud bumps contact only the sides 36 of the solder ball 22 of the IC to be tested and forms the temporary connection while avoiding the center area 34 that is used for a permanent connection. Thus, damage to the solder-ball contact in the area 34 of the permanent connection is avoided. This lowers the number of connection failures and consequently raises the yield.

FIG. 12 is a perspective view of a short tipped stud bump for a solder bump probe 38, and could be formed by depositing a first length of wire or a stud bump 46 having a first diameter on a conductive pad 40 and then depositing a smaller ball shaped wire or stud bump 48 at the top or tip of the larger diameter stud bump. Since the stud bump is shaped so that it contacts the side of the solder ball in the interconnection nest, the “keep out zone” or permanent connection area of the solder ball is avoided. Some of the other possible shapes that the wire bonder can build in the stud bump configuration with various sizes of wire are illustrated in FIGS. 13,14 and 15. FIG. 13 is similar to FIG. 12, except the larger diameter stud bump 46a is longer than in FIG. 12. FIG. 14, is also similar, except the top stud bump 48a is pointed rather than ball shaped. FIG. 15 illustrates the accuracy of the wire bonding machine by showing five (5) small round shaped stud bumps 48b, 48c, 48d, 48e and 48f are all stacked on top of each other as well as the first stud bump 46.

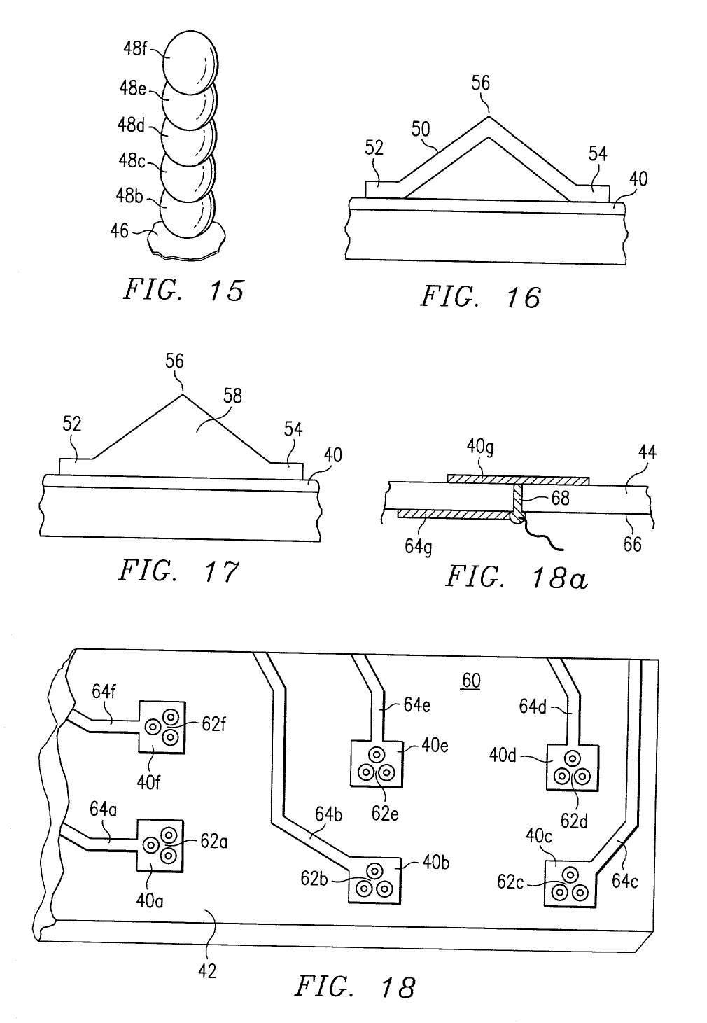

The wire bonding machine can also build up sides of an interconnection nest as illustrated in FIG. 16. According to this method, the bonding wire 50 is strung across the side of the nest site where the solder ball 22 will be seated. A first end 52 of the wire 50 is bonded at one location on conductive pad 40, and then a second end 54, separated from the first, is bonded to a second location on the conductive pad 40 so as to form a side of the interconnection nest. The wire 50 may also be strung so that it forms a raised area or peak 56 in the middle of the wire segment 50 before the second end is bonded to the conductive pad 40. For example, the peaked shape formed in FIG. 16 may be formed. After the wire is bonded at both ends, the fixture may be dipped into a mold compound that fills in the area 58 defined by the wire segment 50. This will give the side of the nest constructed with the wire rigidity sufficient to withstand the forces associated with loading a solder ball into the interconnection nest. The dipped side of an interconnection nest is illustrated in FIG. 17.

The wire bonding machine is a very flexible machine that is normally used to permanently interconnect the IC die product to the package or substrate. This flexibility allows the production of different shapes of stud bumps very rapidly and at a very low cost. The machine can deposit the conductive members that form the sides of the interconnecting nest very accurately in a precise location with software controls. Thus, rigid photo mask and etching processes that have been used in the past to create the area array probe interface are no longer necessary. Further, the wire bonding machine can change the location of a conductive member or nest for the solder balls 22 by simply changing the software that controls the machine. Consequently, probe cards may be designed and manufactured in the time it takes to build the substrate and apply the bonds to their appropriate locations rather than the months typically required by the prior art methods. If rework of a probe tip is necessary the wire bonding machine can locate the site and replace the tip in a matter of seconds.

Of course, to provide testing, each of the conductive members 38 on the probe card are connected to the appropriate circuitry. Therefore, referring now to FIG. 18, there is shown a top view of a probe card 60 illustrating six conductive pads 40a, 40b, 40c, 40d, 40e and 40f on the working surface 42 of a support member, each with an interconnect nest 62 formed by three stud bumps. Also as shown, conductive pathways or traces 64a, 64b, 64c, 64d and 64e are also deposited on the working surface 42 and are routed to connection points (not shown) that will not interfere with the placement of the circuit to be tested on the probe card.

It should be appreciated, however, that the conductive pathways 64g could be formed on the back-side of the substrate such as on the surface 66 opposite the working surface 42. To accomplish this, there will also be a conductive path 68 from the conductive pad 40g on the working surface 42 through the substrate 44 such as by a via to the opposite surface or back side 66 of the substrate. It will also be appreciated that individual wires could be connected at the via instead of depositing conductive traces.

I claim:

1. Apparatus for testing circuitry having an array of solder-ball contacts or connection probes of a selected size, said solder-ball contacts having a contact area and a peripheral area comprising:
a support substrate having a working surface;
a multiplicity of conductive pads mounted on said working surface;
a multiplicity of conductive pathways extending from said multiplicity of conductive paths to test circuitry;
at least one conductive member formed on each of said multiplicity of conductive pads and extending away from said working surface; and
said conductive members formed on said conductive pads positioned on said support substrate to make an electrical connection with said peripheral area of said solder-ball contacts or connection points of a circuit placed against said apparatus.

2. The apparatus of claim 1 wherein said at least one conductive member formed on said conductive pads comprises two conductive members located to receive said peripheral area of a solder-ball contact for making said electrical connection.

3. The apparatus of claim 1 wherein said at least one conductive member formed on said conductive pads comprises three conductive members located to form an interconnection nest for making said electrical connection with said peripheral area.

4. The apparatus of claim 1 wherein said at least one conductive member formed on said conductive pads comprises at least four conductive members located to form an interconnection nest for making said electrical connection with said peripheral area.

5. The apparatus of claim 1 wherein said at least one conductive member is formed from one of gold wire and aluminum wire.

6. The apparatus of claim 1 wherein said at least one conductive member formed on each of said conductive pads comprises a length of wire bonded to said conductive pad.

7. The apparatus of claim 6 wherein said length of wire comprises a formed length of wire having each end thereof bonded to said conductive pad.

8. The apparatus of claim 6 wherein said formed length of wire is formed with a raised area in the middle thereof.

9. The apparatus of claim 8 wherein said length of wire with said raised area is covered with a mold compound to provide rigidity.

10. The apparatus of claim 1 wherein said support substrate comprises a planar insulating material and said conductive pathways comprise conductive traces formed on said planer insulating material.

11. The apparatus of claim 10 wherein said conductive pathways are formed on said working surface.

12. The apparatus of claim 10 wherein said conductive pathways are formed substantially on a surface opposite said working surface and extend from said opposite surface through said insulating material to a conductive pad on said working surface.

13. The apparatus of claim 1 wherein said conductive members are stud bumps deposited by a wire bonding machine.

14. The apparatus of claim 13 wherein one or more of said conductive members comprise stud bumps bonded on top of another stud bump.

15. The apparatus of claim 5 wherein said conductive members are stud bumps deposited by a wire bonding machine.

16. The apparatus of claim 5 wherein said conductive members are stud bumps deposited by a wire bonding machine.

17. Apparatus for testing circuitry having an array of solder-ball contacts of a selected size with a contact area and peripheral area comprising:
a planar insulating support substrate having a working surface and a back surface;
a multiplicity of conductive paths forms on said working surface;
conductive pathways formed on said working surface leading from said multiplicity of conductive pads to testing circuitry;
at least three conductive lengths of wire extending away from said working surface bonded to selected ones of said multiplicity of conductive pads by a wire bonding machine to form an interconnecting nest; and
said interconnecting nest positioned on said support substrate to receive a solder-ball contact point and making an electrical connection with said peripheral area of said received solder-ball for testing said circuitry.

18. A method of manufacturing testing apparatus for circuitry having an array of solder-ball contacts of a selected size and having a contact area and peripheral area comprising the steps of:
providing a support substrate having a working surface and a multiplicity of conductive pads mounted on said working surface;
extending conductive pathways from said multiplicity of conductive pads to testing circuitry;
forming at least one conductive member on each one of said multiplicity of conductive pads, said conductive member extending away from said working surface; and
positioning said first multiplicity of conductive paths with said conductive member on said support structure such that said conductive members are aligned so as to make electrical contact with said periphery area of said array of solder-ball contact points of a circuit placed against said testing apparatus.

19. The method of claim 18 wherein said step of forming comprises forming at least two conductive members.

20. The method of claim 18 wherein said step of forming comprises forming at least three conductive members.

21. The method of claim 18 wherein said step of forming comprises forming at least four conductive members.

22. The method of claim 18 wherein said step of forming at least one conductive member comprises a step of depositing stud bumps on said conductive pads with a wire bonding machine.

23. The method of claim 18 wherein said conductive members are formed from one of gold and aluminum wire.

24. The method of claim 18 and further comprising the step of placing circuitry having an array of solder-ball contact points against said apparatus and testing said circuitry.

25. A method of manufacturing testing apparatus for circuitry having an array of solder-ball contact points of a selected size and a contact area and a peripheral area comprising the steps of:
providing a support substrate having a working surface and a multiplicity of conductive paths formed on said working surface;
forming conductive pathways from said multiplicity of conductive paths to testing circuitry;
depositing at least three stud bumps on said conductive pads with a wire bonding machine to form interconnecting nests for receiving a solder ball contact point; and
positioning said interconnecting nest on said support structure such that said stud bumps are aligned so as to make electrical contact with said array of solder-ball test points of a circuit placed against said testing apparatus.
